(19) United States
(12) Patent Application Publication
(10) Pub. No.: US 2026/0121663 A1
(43) Pub. Date: Apr. 30, 2026

(54) DECODING METHOD AND STORAGE DEVICE

(71) Applicant: Hosin Global Electronics Co., LTD, Shenzhen (CN)

(72) Inventors: Yun-An Fan, Shenzhen (CN); Tsung-Lin Wu, Shenzhen (CN); Chao-Yu Chen, Shenzhen (CN); Qi Ming Zhu, Shenzhen (CN); Hao Wang, Shenzhen (CN); Wei Wang, Shenzhen (CN)

(73) Assignee: Hosin Global Electronics Co., LTD, Shenzhen (CN)

(21) Appl. No.: 19/266,171

(22) Filed: Jul. 11, 2025

(30) Foreign Application Priority Data
Oct. 28, 2024 (CN) 202411513614.X

(51) Int. Cl. H03M 13/11; H03M 13/00

(52) U.S. Cl. CPC H03M 13/1108; H03M 13/6505

(57) ABSTRACT

Disclosed are a decoding method and a storage device. The method includes: reading first data, wherein the first data includes a plurality of bits; performing a decoding operation on the first data to obtain first guidance data and second guidance data, wherein the first guidance data reflects gravity for performing bit flipping on each of the bits, and the second guidance data reflects repulsion for performing bit flipping on each of the bits; generating third guidance data based on the first guidance data and the second guidance data; performing bit flipping on at least one of the plurality of bits based on the third guidance data to obtain a flip result; and performing a second decoding operation on the flip result. In this way, decoding efficiency may be improved.

### CROSS-REFERENCE TO RELATED APPLICATION

This application claims the priority benefit of China application serial no. 202411513614.X, filed on Oct. 28, 2024. The entirety of the above-mentioned patent application is hereby incorporated by reference herein and made a part of this specification.

### BACKGROUND

### Technical Field

The present disclosure relates to a storage technology, and particularly relates to a decoding method and a storage device.

### Description of Related Art

Generally speaking, in order to ensure the correctness of data read from memory modules, the data read from the memory modules may be decoded. In the specific decoding process, Low Density Parity Check (LDPC) is the more commonly used error correction code for correcting error bits in the data. A bit flipping decoder is widely used in practical applications for error correction codes, especially in the decoding process using Low Density Parity Check (LDPC) codes. The bit flipping decoder is a hard-decision decoding method that attempts to correct errors by flipping error bit positions. However, for data containing a substantial number of error bits, bit flipping algorithms also suffer from the problem of decoding degradation.

Therefore, how to effectively improve the decoding efficiency for read data operations while minimizing the increase in complexity of decoding operations constitutes an urgent problem that needs to be resolved at present.

### SUMMARY

The present disclosure provides a decoding method and a storage device that may mitigate the above problems, thereby effectively improving the decoding efficiency of decoding operations for read data operations without increasing the complexity of decoding operations to the greatest extent possible.

Embodiments of the present disclosure provide a decoding method for use in a storage device. The decoding method includes: reading first data, wherein the first data includes a plurality of bits; performing a first decoding operation on the first data to obtain first guidance data and second guidance data, wherein the first guidance data reflects gravity for performing bit flipping on each of the bits, and the second guidance data reflects repulsion for performing the bit flipping on each of the bits; generating third guidance data based on the first guidance data and the second guidance data; performing the bit flipping on at least one of the plurality of bits based on the third guidance data to obtain a flip result; and performing a second decoding operation on the flip result.

Embodiments of the present disclosure further provide a storage device, which includes a connection interface, a memory module, and a memory controller. The connection interface is configured to connect to a host system. The memory controller is connected to the connection interface and the memory module. The memory controller is configured to: read first data from the memory module, wherein the first data includes a plurality of bits; perform a first decoding operation on the first data to obtain first guidance data and second guidance data, wherein the first guidance data reflects gravity for performing bit flipping on each of the bits, and the second guidance data reflects repulsion for performing the bit flipping on each of the bits; generate third guidance data based on the first guidance data and the second guidance data; perform the bit flipping on at least one of the plurality of bits based on the third guidance data to obtain a flip result; and perform a second decoding operation on the flip result.

Based on the above, after reading the first data including a plurality of bits from a first physical unit, the first data may be subjected to the decoding operation to obtain the first guidance data and the second guidance data. The first guidance data may reflect gravity for performing bit flipping on the plurality of bits. The second guidance data may reflect repulsion for performing the bit flipping on the plurality of bits. The third guidance data may be generated based on the first guidance data and the second guidance data, and configured to perform bit flipping on at least one of the plurality of bits. In this way, it is possible to efficiently improve the decoding efficiency of the decoding operation for read data without increasing the complexity of the decoding operation to the greatest extent possible.

### BRIEF DESCRIPTION OF THE DRAWINGS

FIG. 1 is a schematic diagram of a data storage system illustrated according to an embodiment of the present disclosure.

FIG. 2 is a schematic diagram of a memory controller according to an embodiment of the present disclosure.

FIG. 3 is a schematic diagram illustrating management of a memory module according to an embodiment of the present disclosure.

FIG. 4 is a schematic diagram illustrating obtaining first state information according to an embodiment of the present disclosure.

FIG. 5 and FIG. 6 are schematic diagrams illustrating a plurality of iterative decoding operations performed on first data according to embodiments of the present disclosure.

FIG. 7 and FIG. 8 are schematic diagrams of force field information configured to guide bit flipping in decoding operations according to embodiments of the present disclosure.

FIG. 9 is a flowchart of a decoding method illustrated according to an embodiment of the present disclosure.

### DESCRIPTION OF THE EMBODIMENTS

Reference will now be made in detail to exemplary embodiments of the present disclosure, examples of which are illustrated in the accompanying drawings. Wherever possible, the same reference numerals will be used throughout the drawings and the description to refer to the same or like parts.

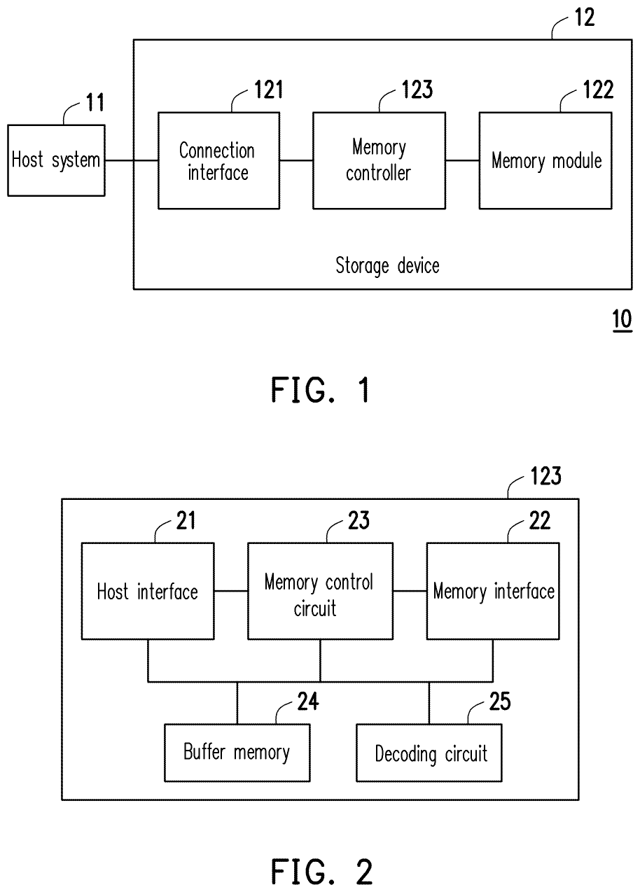

FIG. 1 is a schematic diagram of a data storage system illustrated according to an embodiment of the present disclosure. Refer to FIG. 1, the data storage system 10 includes a host system 11 and a storage device 12. The storage device 12 may be connected to the host system 11 and may be configured to store data from the host system 11. For example, the host system 11 may be a smartphone, a tablet computer, a notebook computer, a desktop computer, an industrial computer, a gaming console, a server, or a computer system disposed in a specific carrier (such as a vehicle, aircraft, or ship), and so on, and the type of the host system 11 is not limited thereto. In addition, the storage device 12 may include a solid-state drive, a USB flash drive, a memory card, or other types of non-volatile storage devices.

The storage device 12 includes a connection interface 121, a memory module 122, and a memory controller 123. The connection interface 121 is configured to connect the storage device 12 to the host system 11. For example, the connection interface 121 may support embedded Multi-Media Card (eMMC), Universal Flash Storage (UFS), Peripheral Component Interconnect Express (PCI Express), Non-Volatile Memory Express (NVM express), Serial Advanced Technology Attachment (SATA), Universal Serial Bus (USB), or other types of connection interface standards. Therefore, the storage device 12 may communicate with the host system 11 through the connection interface 121 (for example, exchange signals, instructions and/or data).

The memory module 122 is configured to store data. For example, the memory module 122 may include one or more rewritable non-volatile memory modules. Each rewritable non-volatile memory module may include one or more memory cell arrays. The memory cells in the memory cell array store data in the form of voltage (also called threshold voltage). For example, the memory module 122 may include Single Level Cell (SLC) NAND flash memory modules, Multi Level Cell (MLC) NAND flash memory modules, Triple Level Cell (TLC) NAND flash memory modules, Quad Level Cell (QLC) NAND flash memory modules and/or other memory modules with the same or similar characteristics.

The memory controller 123 is connected to the connection interface 121 and the memory module 122. The memory controller 123 may be regarded as the control core of the storage device 12 and configured to control the storage device 12. For example, the memory controller 123 may be configured to control or manage the overall or partial operation of the storage device 12. For example, the memory controller 123 may include a Central Processing Unit (CPU), or other programmable general-purpose or special-purpose microprocessor, a Digital Signal Processor (DSP), a programmable controller, an Application Specific Integrated Circuits (ASIC), a Programmable Logic Device (PLD) or other similar devices or combinations of these devices. In an embodiment, the memory controller 123 may include a flash memory controller.

The memory controller 123 may send instruction sequences to the memory module 122 to access the memory module 122. For example, the memory controller 123 may send write instruction sequences to the memory module 122 to instruct the memory module 122 to store data in specific memory cells. For example, the memory controller 123 may send read instruction sequences to the memory module 122 to instruct the memory module 122 to read data from specific memory cells. For example, the memory controller 123 may send erase instruction sequences to the memory module 122 to instruct the memory module 122 to erase data stored in specific memory cells. In addition, the memory controller 123 may also send other types of instruction sequences to the memory module 122 to instruct the memory module 122 to execute other types of operations, which is not limited herein. The memory module 122 may receive instruction sequences from the memory controller 123 and access memory cells inside the memory module 122 based on the instruction sequences.

FIG. 2 is a schematic diagram of a memory controller according to an embodiment of the present disclosure. Refer to FIG. 1 and FIG. 2, the memory controller 123 includes a host interface 21, a memory interface 22, and a memory control circuit 23. The host interface 21 is configured to connect to the host system 11 through the connection interface 121 to communicate with the host system 11. The memory interface 22 is configured to connect to the memory module 122 to access the memory module 122.

The memory control circuit 23 is connected to the host interface 21 and the memory interface 22. The memory control circuit 23 may be configured to control or manage the overall or partial operation of the memory controller 123. For example, the memory control circuit 23 may communicate with the host system 11 through the host interface 21 and access the memory module 122 through the memory interface 22. For example, the memory control circuit 23 may include control circuits such as an embedded controller or a microcontroller. In the following embodiments, the description of the memory control circuit 23 is equivalent to the description of the memory controller 123.

In an embodiment, the memory controller 123 may further include a buffer memory 24. The buffer memory 24 is connected to the memory control circuit 23 and is configured to buffer data. For example, the buffer memory 24 may be configured to buffer instructions from the host system 11, data from the host system 11, and/or data from the memory module 122.

In an embodiment, the memory controller 123 may further include a decoding circuit 25. The decoding circuit 25 is connected to the memory control circuit 23 and is configured to perform an encoding operation or a decoding operation on data to ensure the correctness of the data. For example, the decoding circuit 25 may support various encoding/decoding algorithms such as Low Density Parity Check code (LDPC code), BCH code, Reed-solomon code (RS code), Exclusive OR (XOR) code, and the like. In an embodiment, the memory controller 123 may further include other types of various circuit modules (such as power management circuits, etc.), which is not limited herein.

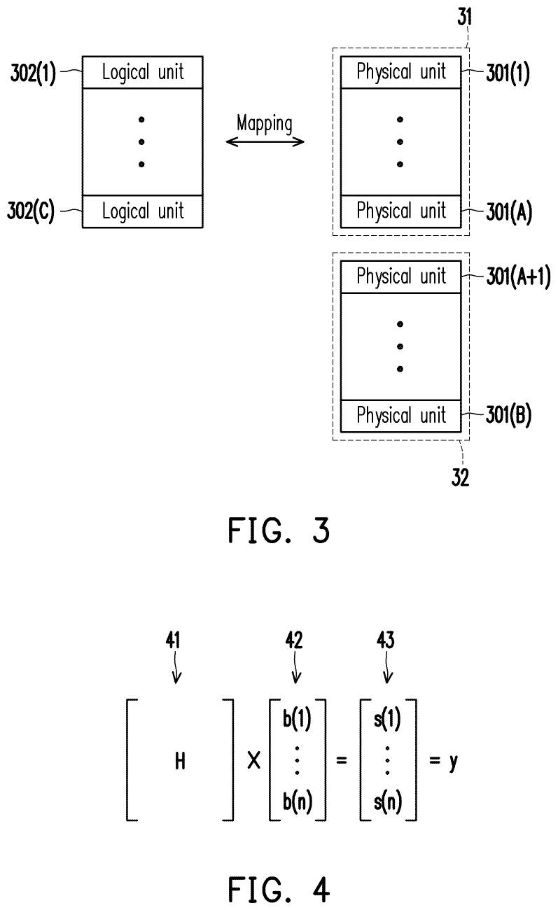

FIG. 3 is a schematic diagram illustrating management of the memory module according to an embodiment of the present disclosure. Refer to FIG. 1 to FIG. 3, the memory module 122 includes a plurality of physical units 301(1)˜301(B). Each physical unit includes a plurality of memory cells and is configured to store data in a non-volatile manner.

In an embodiment, one physical unit may include one or more entity programming units. In an embodiment, one physical programming unit may include plurality of physical sectors. For example, the data capacity of one physical sector may be 512 bytes (B), and one physical programming unit may include 32 physical sectors. However, the data capacity of one physical sector and/or the total number of physical sectors included in one physical programming unit may be adjusted based on practical requirements, and the present disclosure is not limited thereto. In an embodiment, one physical programming unit may be regarded as one physical page. For example, the storage capacity of one physical programming unit may be 16 kilobytes, and the present disclosure is not limited thereto.

In an embodiment, a physical programming unit is the minimum unit for synchronously writing data in the memory module 122. For example, when performing a programming operation (also called a write operation) on a physical programming unit to write data to this physical programming unit, a plurality of memory cells in this physical programming unit may be synchronously programmed to store corresponding data. For example, when a physical programming unit is programmed, a write voltage may be applied to this physical programming unit to change threshold voltages of at least some memory cells in this physical programming unit. For example, a threshold voltage of a memory cell may reflect bit data stored in this memory cell.

In an embodiment, one physical erase unit may include a plurality of physical programming units. The plurality of physical programming units in one physical erase unit may be synchronously erased. For example, when performing an erase operation on one physical erase unit, an erase voltage may be applied to a plurality of physical programming units in this physical erase unit to change threshold voltages of at least some storage cells in these physical programming units. By performing an erase operation on one physical erase unit, data stored in this physical erase unit may be cleared.

In an embodiment, the memory control circuit 23 may logically associate the physical units 301(1)˜301(A) and 301(A+1)˜301(B) with a data area 31 and a spare area 32, respectively. The physical units 301(1)˜301(A) in the data area 31 all store data (also called user data) from the host system 11. For example, any physical unit in the data area 31 may store valid data and/or invalid data. In addition, none of the physical units 301(A+1)˜301(B) in the spare area 32 stores data (for example, valid data).

In an embodiment, if a certain physical unit does not store valid data, this physical unit may be associated to the spare area 32. In addition, the physical unit in the spare area 32 may be erased to clear the data in this physical unit. In an embodiment, the physical unit in the spare area 32 is also called a spare physical unit. In an embodiment, the spare area 32 is also called a free pool.

In an embodiment, when data is to be stored, the memory control circuit 23 may select one or more physical units from the spare area 32 and instruct the memory module 122 to store the data into the selected physical units. After storing the data into the physical unit, the physical unit may be associated with the data area 31. In other words, the one or more physical units may be alternately used between the data area 31 and the spare area 32.

In an embodiment, the memory control circuit 23 may be equipped with a plurality of logical units 302(1)˜302(C) to map the physical units (i.e., physical units 301(1)˜301(A)) in the data area 31. For example, one logical unit may correspond to one Logical Block Address (LBA) or other logical management units. One logical unit may be mapped to one or more physical units.

In an embodiment, if a certain physical unit is currently mapped by any logical unit, the memory control circuit 23 may determine that the data currently stored in this physical unit includes valid data. Conversely, if a certain physical unit is currently not mapped by any logical unit, the memory control circuit 23 may determine that this physical unit currently does not store any valid data.

In an embodiment, the memory control circuit 23 may record a mapping relationship between a logical unit and a physical unit in at least one management table (also called a logical-to-physical mapping table). In an embodiment, the memory control circuit 23 may instruct the memory module 122 to perform a data read operation, a data write operation, or a data erase operation based on information in this management table (i.e., the logical-to-physical mapping table).

In an embodiment, the memory control circuit 23 may read data (also called first data) from at least one physical unit (also called first physical unit) in the memory module 122. For example, the first physical unit may be at least one of the physical units 301(1)˜301(B). The first data includes a plurality of bits. For example, the memory control circuit 23 may send a read command sequence to the memory module 122. The memory module 122 may perform a read operation on the first physical unit based on the read command sequence. The memory module 122 may return the first data to the memory control circuit 23 based on a read result of the read operation.

In an embodiment, after obtaining the first data, the decoding circuit 25 may perform a decoding operation (also called a first decoding operation) on the first data to obtain a plurality of types of guidance data. Then, the decoding circuit 25 may perform bit flipping on at least one bit in the first data based on the plurality of types of guidance data.

In an embodiment, the guidance data includes first guidance data and second guidance data. The first guidance data reflects gravity for performing bit flipping on the plurality of bits in the first data. The second guidance data reflects repulsive force for performing bit flipping on the plurality of bits in the first data.

In an embodiment, the gravity may be configured to improve a probability of performing bit flipping on at least one of the plurality of bits. That is, the greater the gravity reflected by the first guidance data, the higher probability of at least one bit in the first data being flipped (for example, flipped from “1” to “0” or from “0” to “1”) in the first decoding operation.

In an embodiment, the repulsive force may be configured to reduce a probability of performing bit flipping on the at least one of the plurality of bits. That is, the greater the repulsive force reflected by the second guidance data, the lower probability of at least one bit in the first data being flipped (for example, flipped from “1” to “0” or from “0” to “1”) in the first decoding operation.

In an embodiment, the memory control circuit 23 may generate another guidance data (also called third guidance data) based on the first guidance data and the second guidance data. The decoding circuit 25 may perform bit flipping on at least one bit in the first data based on the third guidance data. For example, the decoding circuit 25 may flip at least one bit (also called first bit) in the first data from “1” to “O” and/or flip at least one bit (also called second bit) in the first data from “0” to “1” based on the third guidance data.

In an embodiment, in the first decoding operation, the memory control circuit 23 may obtain state information (also called first state information) related to the plurality of bits in the first data. The first state information may reflect a current state of the plurality of bits. For example, the first state information may reflect that some bits in the first data are error bits and/or some bits in the first data are not error bits.

FIG. 4 is a schematic diagram illustrating obtaining the first state information according to an embodiment of the present disclosure. Refer to FIG. 4, in an embodiment, assume that the first data include a codeword 42, and the codeword 42 include bits b(1)˜b(n).

In an embodiment, in the first decoding operation, the decoding circuit 25 may obtain a vector 43 (i.e., first state information) based on a parity check matrix 41 (also called H matrix) and the codeword 42. For example, the decoding circuit 25 may perform a matrix multiplication on the parity check matrix 41 and the codeword 42, and obtain the vector 43 based on an operation result of the matrix multiplication. In an embodiment, the vector 43 is also called a vector y. The vector 43 (i.e., first state information) may reflect a current state of the codeword 42 (i.e., first data).

Specifically, the size of the first data read by each variable node (B node) before each parity check mainly depends on the following factors:
1. Number of variable nodes: Each parity check node (C node) needs to read data from all variable nodes connected thereto. In the parity check matrix H, the number of rows represents the number of the parity check nodes (C nodes). Each row represents a plurality of variable nodes connected to one parity check node, and the number of connections is determined by the number of columns with a value of 1 in that row.
2. Amount of data sent by each variable node: Under normal circumstances, each variable node may send one bit of information (0 or 1) to the connected parity check node (C node) to indicate the current bit state. Therefore, each parity check node receives 1 bit of data from each connected variable node.

Exemplarily, assume that the parity check matrix H has the following structure:

$$H = [ \begin{matrix}1 & 0 & 1 & 1 & 0 & 0 \\ 0 & 1 & 0 & 1 & 1 & 0 \\ 1 & 1 & 0 & 0 & 1 & 1\end{matrix} ]$$

Then the number of parity check nodes (C nodes) in the above His 3, and the number of variable nodes (B nodes) connected thereto is 6. The nodes of the parity check matrix H are set by row as: C1, C2, and C3.

Before each parity check: C1 reads data from the connected B nodes as: b1, b3, b4, with corresponding data size of: 3 bits (3 0s or 1s); C2 (parity check node 2) reads data from the connected B nodes as: b2, b4, b5, with corresponding data size of: 3 bits (3 0s or 1s); C3 (parity check node 3) reads data from the connected B nodes as: b1, b2, b5, b6, with corresponding data size of: 4 bits (4 0s or 1s).

Wherein the amount of data read by each parity check node is equal to the number of variable nodes connected thereto multiplied by the data size (typically 1 bit) sent by each variable node. Correspondingly, the amount of data read by all parity check nodes: if there are m parity check nodes and n variable nodes in total, then the total amount of data read is the total number of variable nodes connected to all parity check nodes. (For example, if the number of variable nodes connected to each parity check node is d1, d2, . . . , dm respectively, then the total amount of data is d₁+d₂+ . . . +dₘ bits).

Then in the above example, the total amount of data read is: 3+3+4=10 bits. Therefore, before each parity check, the total amount of data read is determined by the number of connections in the parity check matrix. The amount of data read by each parity check node is the number of variable nodes connected thereto, and each connected variable node transmits 1 bit of data.

It should be noted that, in existing solutions, if flip processing is performed on the above-mentioned 10 bits in the example, it will require 10 times of iteration processing (i.e., judgment before selecting one target bit for flip processing each time). However, based on the method provided in the solution of the present disclosure, it is only necessary to select at least one bit for flip processing based on each calculation result, thereby improving coding efficiency. In addition, the data size read each time in the solution of the present disclosure may be determined based on the dimension of the parity check matrix, or data of a preset size may be adopted for the read operation, including but not limited to: 8 bits, 16 bits, 1 KB size, and so on, which is not specifically limited herein.

In an embodiment, the vector 43 includes bits s(1)˜s(n). Each of the bits s(1)˜s(n) is also called a syndrome. In particular, the value of a bit s(i) may reflect whether a bit b(i) in the codeword 42 is an error bit. For example, if the bit s(i) is “1”, there is a high probability that the bit b(i) in the codeword 42 is an error bit. Conversely, if the bit s(i) is “0”, there is a high probability that the bit b(i) in the codeword 42 is not an error bit. In an embodiment, if the bits s(1)˜s(n) are all “0”, it indicates that no error bit exists in the codeword 42. If no error bit exists in the codeword 42, then the decoding circuit 25 may output successfully decoded data and stop decoding.

It should be noted that, based on the parity check matrix 41, values of the plurality of bits in the vector 43 may be affected by the same bit in the codeword 42. Therefore, the error bit in the codeword 42 cannot be accurately located simply based on the vector 43.

Conventionally, in order to determine the bit (i.e., the error bit) to be flipped in the current decoding operation, the memory control circuit 23 may obtain a syndrome sum corresponding to each bit in the codeword 42 by referring to the parity check matrix 41. Then, the memory control circuit 23 may determine the bit in the codeword 42 corresponding to the maximum syndrome sum as the error bit and perform bit flipping on this bit (for example, flipping the bit from “1” to “0” or from “0” to “1”). By flipping a small number of bits one by one in a plurality of iterations, attempts to correct all errors in the codeword 42 may be possibly achieved.

However, the disadvantages of such error correction method are also evident, namely that only a very small number of bits can be flipped in each iteration. Once the total number of bits flipped in any given iteration becomes excessive, it is highly likely that the flipping operations performed in that iteration will be ineffective, and may even result in error divergence. Therefore, it is necessary to make further improvements to effectively enhance the decoding efficiency of decoding operations with respect to read data, while avoiding any increase in the complexity of the decoding operations to the greatest extent possible.

In an embodiment, in the first decoding operation, the memory control circuit 23 may further obtain another state information (also called second state information) related to the plurality of bits in the first data. The second state information may reflect a target state of the plurality of bits. For example, in an embodiment, the second state information may include a vector x, then the plurality of bits in the vector x are all “0”. In other words, the target state of the plurality of bits reflected by the second state information is an expected final state of the vector y in FIG. 4. Once the bits s(1)˜s(n) in the vector y are all “0”, it indicates that no error bit exists in the codeword 42 (i.e., the first data) being decoded.

It should be noted that setting the target state (for example: [00000]) here is an assumption, that is, the data received by a receiving end should be in a known ideal state in the case of no error. For example, in some coding schemes, the target state may be all zeros (set in this way in the construction of error correction codes), so the goal of the algorithm is to flip the bits to this assumed target state as close as possible.

Actually, the receiving end may only know that the current read data is in a state y without knowing whether the current read data is correct or not. The read data may include errors, but the receiving end does not know the specific position of the error. Therefore, the goal of the error correction process is to gradually correct these errors. It does not know what the ideal target state is, but only uses an assumed target state to guide error correction. The algorithm continuously iterates, and performs bit flipping based on parity check results and rules to make a received signal conforms to a preset target state as much as possible.

In practical applications, the target state is unknown, and by using the error correction algorithm adopted (for example: bit-flipping algorithm), redundant information provided by the parity check nodes (C nodes) is configured to detect and correct received error bit positions. This process is independent of an explicit target state, where the target state serves merely as a hypothetical guide for determining the direction of flipping.

In an embodiment, the memory control circuit 23 may obtain distance information (also called first distance information) based on the first state information and the second state information. The first distance information may reflect a Euclidean distance (also called Euclidean metric) between the current state and the target state. For example, the memory control circuit 23 may obtain the first distance information based on the following formula (1.1).

$$D ( 1 ) = ‖ y - x ‖ \qquad ( 1.1 )$$

In the formula (1.1), the vector x represents the target state of the plurality of bits in the first data, the vector y represents the current state of the plurality of bits, and D(1) is the first distance information. Then, the memory control circuit 23 may obtain the first guidance data based on the first distance information.

In an embodiment, the memory control circuit 23 may obtain gravitational potential field information corresponding to the first data based on the first distance information. In particular, the gravitational potential field information may be configured to simulate a gravitational potential field for pulling the plurality of bits in the first data from the current state toward the target state. For example, the memory control circuit 23 may obtain the gravitational potential field information based on the following formula (1.2).

$$U 1 ( y ) = \frac{1}{2} \times k ( 1 ) \times {D ( 1 )}^{2} \qquad ( 1.2 )$$

In the formula (1.2), k(1) is an attractive force constant, and U1(y) is gravitational potential field information. In particular, k(1) may be adopted to control the strength of the gravitational potential field. For example, a value of k(1) is positively correlated with the strength of the gravitational potential field. In an embodiment, k(1) may be set as a large value to accelerate pulling the plurality of bits in the first data from the current state toward the target state, but over-correction may also occur as a result. In an embodiment, k(1) may be set as a small value to slow down pulling the plurality of bits in the first data from the current state toward the target state, but the number of iterations may increase as a result. In an embodiment, the value of k(1) may be set based on experiences and may be dynamically adjusted. Then, the memory control circuit 23 may obtain the first guidance data based on the gravitational potential field information.

In an embodiment, the memory control circuit 23 may obtain gravitational field gradient information based on the gravitational potential field information. In particular, the gravitational field gradient information may be configured to simulate a gradient of the gravitational potential field. For example, the memory control circuit 23 may obtain the gravitational field gradient information based on the following formula (1.3).

$$∇ U 1 ( y ) = k ( 1 ) \times D ( 1 ) \qquad ( 1.3 )$$

In the formula (1.3), ∇U1(y) is the gravitational field gradient information. Then, the memory control circuit 23 may obtain the first guidance data based on the gravitational field gradient information. For example, the first guidance data may include the gravitational field gradient information.

In an embodiment, in the first decoding operation, the memory control circuit 23 may further obtain another state information (also called third state information) related to the plurality of bits in the first data. The third state information may reflect a repulsion state of the plurality of bits in the first data. For example, in an embodiment, the third state information may include a vector z. A plurality of bits in the vector z may all be “1”. In other words, the repulsion state of the plurality of bits reflected by the third state information is a reverse state of the vector x.

In an embodiment, the memory control circuit 23 may obtain distance information (also called second distance information) based on the first state information and the third state information. The second distance information may reflect the Euclidean distance (i.e., Euclidean metric) between the current state and the repulsion state. For example, the memory control circuit 23 may obtain the second distance information based on the following formula (2.1).

$$D ( 2 ) = ‖ y - z ‖ \qquad ( 2.1 )$$

In the formula (1.1), the vector z represents the repulsion state of the plurality of bits in the first data, and D(2) is the second distance information. Then, the memory control circuit 23 may obtain the second guidance data based on the second distance information.

In an embodiment, the memory control circuit 23 may obtain repulsive potential field information corresponding to the first data based on the second distance information. In particular, the repulsive potential field information may be configured to simulate a repulsive potential field configured to resist pulling the plurality of bits in the first data from the current state to the target state. For example, the memory control circuit 23 may obtain the repulsive potential field information based on the following formulas (2.2) and (2.3).

$$U 2 ( y ) = {\sum }_{i = 1}^{n} [ \frac{1}{2} \times F ( 2 ) \times {( \frac{1}{D ( 2 )} - \frac{1}{d} )}^{2} ] , if D ( 2 ) \leq d \qquad ( 2.2 )$$

$$U 2 ( y ) = 0 , if D ( 2 ) > d \qquad ( 2.3 )$$

In the formula (2.2) and (2.3), k(2) is a repulsive force constant, d is a distance threshold value, and U2(y) is the repulsive potential field information. In particular, k(2) may be configured to control a strength of the repulsive potential field. For example, a value of k(2) is positively correlated with the strength of the repulsive potential field. In an embodiment, k(2) may be set as a large value to improve the resistance of the repulsive potential field against the gravitational potential field. In an embodiment, k(2) may be set as a small value to reduce the resistance of the repulsive potential field against the gravitational potential field. In an embodiment, the value of k(2) may be set based on experiences and may be dynamically adjusted. Then, the memory control circuit 23 may obtain the second guidance data based on the repulsive potential field information.

In an embodiment, the memory control circuit 23 may obtain repulsive field gradient information based on the repulsive potential field information. In particular, the repulsive field gradient information may be configured to simulate a gradient of the repulsive potential field. For example, the memory control circuit 23 may obtain the repulsive field gradient information based on the following formulas (2.4) and (2.5).

$$∇ U 2 ( y ) = {\sum }_{i = 1}^{n} [ k ( 2 ) \times ( \frac{1}{D ( 2 )} - \frac{1}{d} ) \times \frac{1}{{D ( 2 )}^{2}} ] , if D ( 2 ) \leq d \qquad ( 2.4 )$$

$$∇ U 2 ( y ) = 0 , if D ( 2 ) > d \qquad ( 2.5 )$$

In the formula (2.4) and (2.5), ∇U2(y) is the repulsive field gradient information. Then, the memory control circuit 23 may obtain the second guidance data based on the repulsive field gradient information. For example, the second guidance data may include the repulsive field gradient information.

In an embodiment, the memory control circuit 23 may obtain synthesized gradient data based on the first guidance data and the second guidance data. In particular, the synthesized gradient data may be configured to simulate a gradient of a synthesized potential field corresponding to the first data, and the synthesized potential field consists of a gravitational potential field and a repulsive potential field. For example, the memory control circuit 23 may obtain the synthesized gradient data based on the following formula (3.1).

$$F ( y ) = - ∇ U 1 ( y ) - ∇ U 2 ( y ) \qquad ( 3.1 )$$

In the formula (3.1), F(y) represents synthesized gradient data. Then, the memory control circuit 23 may generate the third guidance data based on the synthesized gradient data. For example, the third guidance data may include the synthesized gradient data.

In an embodiment, the memory control circuit 23 may obtain a plurality of gradient information respectively corresponding to the plurality of bits in the first data based on the third guidance data. The memory control circuit 23 may compare the plurality of gradient information to obtain a comparison result. Then, the memory control circuit 23 may flip at least one of the plurality of bits based on the comparison result.

In an embodiment, F(y) includes f(1)˜f(n) (i.e., gradient information). f(1)˜f(n) respectively correspond to the plurality of bits in the first data. For example, f(i) may reflect a gradient corresponding to an i-th bit in the first data. In an embodiment, the memory control circuit 23 may compare f(1)˜f(n). Then, the memory control circuit 23 may determine the bit to be flipped in the first data based on the maximum one among f(1)˜f(n). For example, assuming the maximum one among f(1)˜f(n) is f(i), then in the first decoding operation, the decoding circuit 25 may perform bit flipping on the i-th bit in the first data, for example, flipping the i-th bit in the first data from “1” to “0” or from “0” to “1”. In addition, one or multiple bits may flipped in each iteration, and the present disclosure does not impose limitations thereon. It should be noted that all the above formulas may be adjusted based on practical requirements, and the present disclosure does not impose limitations thereon.

It should be noted that when selecting target bit positions for flipping operations based on the results calculated in each iteration, in extreme cases, all bit positions may have the same gradient information. In this case, if all bit positions are directly subject to flipping operations, non-convergence may occur. However, if the flipping operation is not executed at all, it will obviously result in a deadlock where iteration cannot continue. Therefore, in actual scenarios, to avoid such situation, the following solutions may be adopted.
1. Introducing random perturbation: In the case where resultant forces are the same, a small random perturbation may be introduced (i.e., randomly selecting to flip or not flip), which may break the balance, thereby avoiding an infinite loop or flipping all bit positions. For example: one or a few of all bit positions of gradient information are randomly selected as target bit positions for flipping.

Such strategy ensures that an excessive number of bit positions will not be flipped in a single iteration, thereby maintaining a gradual process of approaching the target state.
2. Selection based on historical information: A flip history of each bit position in previous iterations is recorded, and a flip order is determined in combination with current gradient information. For example: those bit positions that have been flipped fewer times in the previous iterations are selected for flipping.

Such method may ensure a more uniform selection of each flipping, thus reducing the possibility of repeatedly switching back and forth between the same states.
3. Prioritized selection of the most sensitive bit positions: Through analysis of the degree of influence each bit position exerts upon the overall potential field, the bit positions most sensitive to potential field variations are selected for bit flipping operations. For example: a local potential field variation for each bit position is calculated, namely calculating the change to the overall potential field resulting from flipping said bit position; those bit positions that contribute maximally to potential field variations are flipped with high priorities.
4. Introducing a dynamic adjustment mechanism: A dynamic adjustment mechanism is introduced in the flip strategy to adjust the flip strategy based on the change of the potential field during the iteration process. For example: in an early stage of iteration, more bit positions may be selected for flipping to quickly approach the target state; when close to convergence, the number of flipped bit positions in each iteration is reduced to improve the stability and the convergence speed.

Specifically, a single-point flip (or minority flip) strategy may ensure that state change is relatively small each time, helping to gradually approach the target state. A strategy based on history or sensitivity may reduce unnecessary flips and prevent switching back and forth between the same states. A dynamic adjustment strategy may make the algorithm more flexible, allow adaptively adjustment to the flip strategy based on the current state, and improve the convergence speed and the reliability.

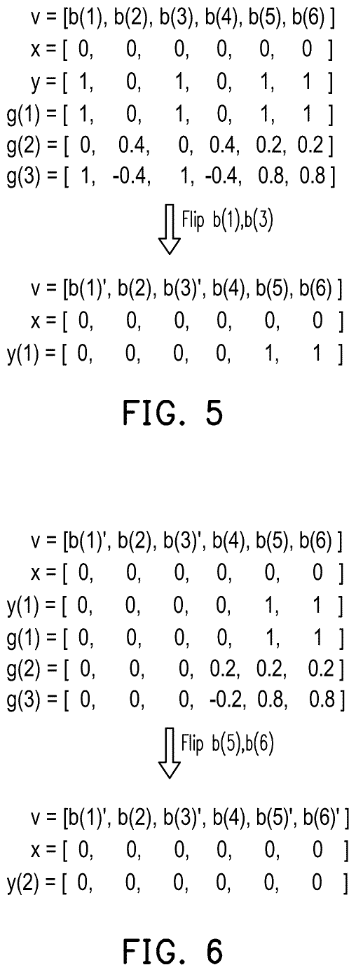

FIG. 5 and FIG. 6 are schematic diagrams illustrating a plurality of iterative decoding operations performed on the first data according to embodiments of the present disclosure. Refer to FIG. 5, in an embodiment, assume that a codeword in the first data is represented by a vector v. For example, the vector v includes bits b(1)˜b(6). For example, the vector v=[b(1), b(2), b(3), b(4), b(5), b(6)].

In a first iterative decoding on the vector v (i.e., [b(1), b(2), b(3), b(4), b(5), b(6)]), the decoding circuit 25 may obtain the vector x (i.e., second state information) and the vector y (i.e., first state information). The vector x may reflect the respective target states of the bits b(1)˜b(6) in the vector v. For example, the vector x=[0, 0, 0, 0, 0, 0]. In addition, the vector y may reflect the respective current states of the bits b(1)˜b(6) in the vector v. For example, the vector y=[1, 0, 1, 0, 1, 1].

In an embodiment, the memory control circuit 23 may obtain a vector g(1) (i.e., the first guidance information) based on formulas (1.1)˜(1.3), and obtain a vector g(2) (i.e., the second guidance information) based on formulas (2.1)˜(2.5). Then, the memory control circuit 23 may obtain a vector g(3) (i.e., the third guidance information) based on the vectors g(1) and g(2). Based on the third guidance information, the memory control circuit 23 (or the decoding circuit 25) may perform bit flipping on the bits b(1) and b(3) in the vector v. For example, the memory control circuit 23 (or the decoding circuit 25) may flip the bits b(1) and b(3) in the vector v to b(1)′ and b(3)′, respectively. Under the circumstances, a result of the first iterative decoding on the vector v is to update the vector v to [b(1)′, b(2), b(3)′, b(4), b(5), b(6)].

Based on the updated vector v, the decoding circuit 25 may obtain an updated vector y (i.e., y(1)). For example, a vector y(1)=[0, 0, 0, 0, 1, 1]. Compared to the vector y, the vector y(1) reflects that the bits b(1) and b(3) in the vector v that were originally error bits have been corrected (i.e., bits b(1) to b(4) in the vector v are all non-error bits). However, the vector y(1) is different from the vector x. Therefore, the memory control circuit 23 and the decoding circuit 25 may perform a second iterative decoding on the vector v.

Refer to FIG. 6, in continuation of the embodiment of FIG. 5, in the second iterative decoding on the vector v (i.e., [b(1)′, b(2), b(3)′, b(4), b(5), b(6)]), the memory control circuit 23 may again obtain the vector g(1) (i.e., the first guidance information) based on the formulas (1.1)˜(1.3), and obtain the vector g(2) (i.e., the second guidance information) based on the formulas (2.1)˜(2.5). Then, the memory control circuit 23 may obtain the vector g(3) (i.e., the third guidance information) based on the vectors g(1) and g(2). Based on the third guidance information, the memory control circuit 23 (or decoding circuit 25) may perform bit flipping on the bits b(5) and b(6) in the vector v. For example, the memory control circuit 23 (or decoding circuit 25) may flip the bits b(5) and b(6) in the vector v to b(5)′ and b(6)′, respectively. Under the circumstances, a result of the second iterative decoding on the vector v is to update the vector v to [b(1)′, b(2), b(3)′, b(4), b(5)′, b(6)′].

Based on the updated vector v, the decoding circuit 25 may obtain an updated vector y (i.e., y(2)). For example, a vector y(2)=[0, 0, 0, 0, 0, 0]. Compared to the vector y(1), the vector y(2) reflects that the bits b(5) and b(6) which were originally error bits in the vector v have been corrected (i.e., the bits b(1) to b(6) in the vector v are all non-error bits). At this point, the vector y(2) is identical to the vector x. Therefore, the memory control circuit 23 and the decoding circuit 25 may determine that decoding on the first data (i.e., vector v) is successful and output the decoded first data.

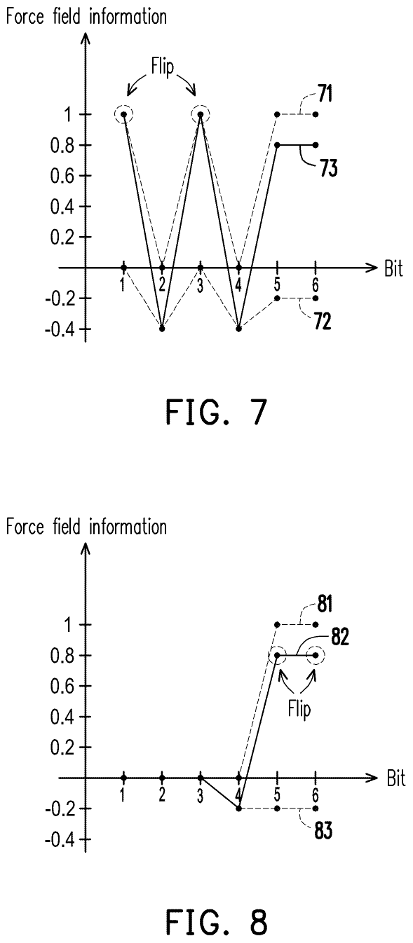

FIG. 7 and FIG. 8 are schematic diagrams of force field information configured to guide bit flipping in decoding operations according to embodiments of the present disclosure. Referring to FIG. 7, curves 71, 72, and 73 may respectively present, in the embodiment of FIG. 5, force field information of the vector g(1) (i.e., first guidance information), the vector g(2) (i.e., second guidance information), and the vector g(3) (i.e., third guidance information) respectively corresponding to the plurality of bits b(1)˜b(6) in the first data (i.e., vector v).

Specifically, the force field information presented by the curve 71 is configured to simulate a gravitational potential field that pulls the bits b(1)˜b(6) from the current state toward the target state. The force field information presented by the curve 72 is configured to simulate a repulsive potential field that resists pulling the bits b(1)˜b(6) from the current state toward the target state. In addition, the force field information presented by the curve 73 is configured to simulate a synthesized force potential field formed by the gravitational potential field and the repulsive potential field. Based on an extreme value position of the curve 73, the bits b(1) and b(3) in the first data (i.e., vector v) may be flipped.

Refer to FIG. 8, curves 81, 82, and 83 may respectively present, in the embodiment of FIG. 6, force field information of the vector g(1) (i.e., the first guidance information), the vector g(2) (i.e., the second guidance information), and the vector g(3) (i.e., the third guidance information) respectively corresponding the plurality of bits b(1)′, b(2), b(3)′, b(4)˜b(6) in the first data (i.e., vector v).

Specifically, the force field information presented by the curve 81 is configured to simulate a gravitational potential field that pulls the bits b(1)′, b(2), b(3)′, b(4)˜b(6) from the current state to the target state. The force field information presented by the curve 82 is configured to simulate a repulsive potential field that resists pulling the bits b(1)′, b(2), b(3)′, b(4)˜b(6) from the current state to the target state. In addition, the force field information presented by the curve 83 is configured to simulate the synthesized force potential field formed by the gravitational potential field and the repulsive potential field. Based on an extreme value position of the curve 83, the bits b(5) and b(6) in the first data (i.e., vector v) may be flipped.

It should be noted that, for the embodiment of FIG. 5, if a conventional bit flip algorithm is adopted to determine the bit to be flipped in each iteration, it may require execution of 4 or more iterative decoding operations to completely correct all errors in the first data (i.e., vector v). However, in the embodiments of FIG. 5 and FIG. 6 (in conjunction with FIG. 7 and FIG. 8), by executing only 2 iterative decoding operations, all errors in the first data (i.e., vector v) may be completely corrected. Thus, the decoding efficiency of read operations for read data may be effectively improved without increasing the complexity of the decoding operation to the greatest extent possible.

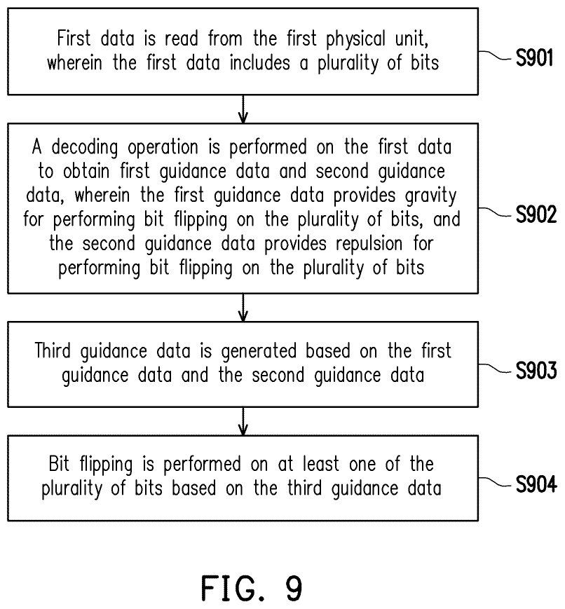

FIG. 9 is a flowchart of a decoding method illustrated according to an embodiment of the present disclosure. Specifically, please refer to the steps shown in FIG. 9 as follows.

In step S901, first data is read from the first physical unit, wherein the first data includes the plurality of bits.

In step S902, the decoding operation is performed on the first data to obtain the first guidance data and the second guidance data, wherein the first guidance data reflects (or provides) gravity for performing bit flipping on the plurality of bits, and the second guidance data reflects (or provides) repulsion for performing bit flipping on the plurality of bits.

In step S903, the third guidance data is generated based on the first guidance data and the second guidance data.

In step S904, bit flipping is performed on at least one of the plurality of bits based on the third guidance data.

The steps in FIG. 9 have been described in detail above, and thus will not be repeated here. It is worth noting that the steps in FIG. 9 may be implemented as plurality of program codes or circuits, and the present disclosure is not limited thereto. In addition, the method in FIG. 9 may be used in conjunction with the above exemplary embodiments, or may be used alone, and the present disclosure is not limited thereto.

In summary, the decoding method and the storage device provided by the embodiments of the present disclosure may simulate the pulling between gravity and repulsion for each bit in the data to be decoded. In particular, the gravity is configured to pull each bit in the data to be decoded toward the target state of decoding, while the repulsion is configured to resist pulling each bit in the data to be decoded toward the target state. Based on the simulation result of the gravity and repulsion, at least some of the bits in the data to be decoded may be flipped. Thus, the decoding efficiency of the decoding operation for read data may be effectively improved without increasing the complexity of the decoding operation to the greatest possible.

Finally, it should be noted that: the above embodiments are only configured to illustrate the technical solutions of the present disclosure, rather than to limit them; although the present disclosure has been described in detail with reference to the aforementioned embodiments, those of ordinary skill in the art should understand that: they may still modify the technical solutions described in the aforementioned embodiments, or perform equivalent substitutions for some or all of the technical features thereof; and these modifications or substitutions do not cause the essence of the corresponding technical solutions to depart from the scope of the technical solutions in the embodiments of the present disclosure.

What is claimed is:

1. A decoding method, for use in a storage device, wherein the decoding method comprises:
reading first data, wherein the first data comprises a plurality of bits;
performing a first decoding operation on the first data to obtain first guidance data and second guidance data, wherein the first guidance data reflects gravity for performing bit flipping on each of the bits, and the second guidance data reflects repulsion for performing the bit flipping on each of the bits;
generating third guidance data based on the first guidance data and the second guidance data;
performing the bit flipping on at least one of the plurality of bits based on the third guidance data to obtain a flip result; and
performing a second decoding operation on the flip result.

2. The decoding method according to claim 1, wherein the gravity is configured to improve a probability of performing the bit flipping on the at least one of the plurality of bits, and the repulsion is configured to reduce the probability of performing the bit flipping on the at least one of the plurality of bits.

3. The decoding method according to claim 1, wherein the step of performing the first decoding operation on the first data to obtain the first guidance data comprises:
determining first state information based on the first data, wherein the first state information reflects a current state of the plurality of bits;
obtaining first distance information based on the first state information and a target state information, wherein the target state information is configured to reflect a target state that the flip result is expected to ultimately reach, the first distance information reflects a Euclidean distance between the current state and the target state; and
obtaining the first guidance data based on the first distance information.

4. The decoding method according to claim 3, wherein the step of obtaining the first guidance data based on the first distance information comprises:
obtaining gravitational potential field information corresponding to the first data based on the first distance information, wherein the gravitational potential field information is configured to simulate a gravitational potential field for flipping the plurality of bits from the current state to the target state; and
obtaining the first guidance data based on the gravitational potential field information.

5. The decoding method according to claim 4, wherein the step of obtaining the first guidance data based on the gravitational potential field information comprises:
obtaining gravitational field gradient information based on the gravitational potential field information, wherein the gravitational field gradient information is configured to simulate a gradient of the gravitational potential field; and
obtaining the first guidance data based on the gravitational field gradient information.

6. The decoding method according to claim 1, wherein the step of performing the first decoding operation on the first data to obtain the second guidance data comprises:
obtaining first state information of the plurality of bits, wherein the first state information reflects a current state of the plurality of bits;
obtaining third state information of the plurality of bits, wherein the third state information reflects a repulsion state of the plurality of bits;
obtaining second distance information based on the first state information and the third state information, wherein the second distance information reflects a Euclidean distance between the current state and the repulsion state; and
obtaining the second guidance data based on the second distance information.

7. The decoding method according to claim 6, wherein the step of obtaining the second guidance data based on the second distance information comprises:
obtaining repulsive potential field information corresponding to the first data based on the second distance information, wherein the repulsive potential field information is configured to simulate a repulsive potential field configured to resist pulling the plurality of bits from the current state to a target state; and
obtaining the second guidance data based on the repulsive potential field information.

8. The decoding method according to claim 7, wherein the step of obtaining the second guidance data based on the repulsive potential field information comprises:
obtaining repulsive field gradient information based on the repulsive potential field information, wherein the repulsive field gradient information is configured to simulate a gradient of the repulsive potential field; and
obtaining the second guidance data based on the repulsive field gradient information.

9. The decoding method according to claim 1, wherein the step of generating the third guidance data based on the first guidance data and the second guidance data comprises:
obtaining synthesized gradient data based on the first guidance data and the second guidance data, wherein the synthesized gradient data is configured to simulate a gradient of a synthesized potential field corresponding to the first data, and the synthesized potential field consists of a gravitational potential field and a repulsive potential field; and
generating the third guidance data based on the synthesized gradient data.

10. The decoding method according to claim 1, wherein the step of performing the bit flipping on the at least one of the plurality of bits based on the third guidance data comprises:
obtaining a plurality of gradient information respectively corresponding to the plurality of bits based on the third guidance data;
comparing the plurality of gradient information to obtain a comparison result; and
flipping the at least one of the plurality of bits based on the comparison result.

11. A storage device, comprising:
a connection interface, configured to connect to a host system;
a memory module; and
a memory controller, connected to the connection interface and the memory module,
wherein the memory controller is configured to:
read first data from the memory module, wherein the first data comprises a plurality of bits;
perform a first decoding operation on the first data to obtain first guidance data and second guidance data, wherein the first guidance data reflects gravity for performing bit flipping on each of the bits, and the second guidance data reflects repulsion for performing the bit flipping on each of the bits;
generate third guidance data based on the first guidance data and the second guidance data;
perform the bit flipping on at least one of the plurality of bits based on the third guidance data to obtain a flip result; and
perform a second decoding operation on the flip result.

12. The storage device according to claim 11, wherein the gravity is configured to improve a probability of performing the bit flipping on the at least one of the plurality of bits, and the repulsion is configured to reduce the probability of performing the bit flipping on the at least one of the plurality of bits.

13. The storage device according to claim 11, wherein the step of performing the first decoding operation on the first data by the memory controller to obtain the first guidance data comprises:
determining first state information based on the first data, wherein the first state information reflects a current state of the plurality of bits;
obtaining first distance information based on the first state information and a target state information, wherein the target state information is configured to reflect a target state that the flip result is expected to ultimately reach, the first distance information reflects a Euclidean distance between the current state and the target state; and
obtaining the first guidance data based on the first distance information.

14. The storage device according to claim 13, wherein the step of obtaining the first guidance data by the memory controller based on the first distance information comprises:
obtaining gravitational potential field information corresponding to the first data based on the first distance information, wherein the gravitational potential field information is configured to simulate a gravitational potential field for flipping the plurality of bits from the current state to the target state; and
obtaining the first guidance data based on the gravitational potential field information.

15. The storage device according to claim 14, wherein the step of obtaining the first guidance data by the memory controller based on the gravitational potential field information comprises:
obtaining gravitational field gradient information based on the gravitational potential field information, wherein the gravitational field gradient information is configured to simulate a gradient of the gravitational potential field; and
obtaining the first guidance data based on the gravitational field gradient information.

16. The storage device according to claim 11, wherein the step of performing the first decoding operation on the first data by the memory controller to obtain the second guidance data comprises:
obtaining first state information of the plurality of bits, wherein the first state information reflects a current state of the plurality of bits;
obtaining third state information of the plurality of bits, wherein the third state information reflects a repulsion state of the plurality of bits;
obtaining second distance information based on the first state information and the third state information, wherein the second distance information reflects a Euclidean distance between the current state and the repulsion state; and
obtaining the second guidance data based on the second distance information.

17. The storage device according to claim 16, wherein the step of obtaining the second guidance data by the memory controller based on the second distance information comprises:
obtaining repulsive potential field information corresponding to the first data based on the second distance information, wherein the repulsive potential field information is configured to simulate a repulsive potential field configured to resist pulling the plurality of bits from the current state to a target state; and
obtaining the second guidance data based on the repulsive potential field information.

18. The storage device according to claim 17, wherein the step of obtaining the second guidance data by the memory controller based on the repulsive potential field information comprises:
obtaining repulsive field gradient information based on the repulsive potential field information, wherein the repulsive field gradient information is configured to simulate a gradient of the repulsive potential field; and
obtaining the second guidance data based on the repulsive field gradient information.

19. The storage device according to claim 11, wherein the step of generating the third guidance data by the memory controller based on the first guidance data and the second guidance data comprises:
obtaining synthesized gradient data based on the first guidance data and the second guidance data, wherein the synthesized gradient data is configured to simulate a gradient of a synthesized potential field corresponding to the first data, and the synthesized potential field consists of a gravitational potential field and a repulsive potential field; and
generating the third guidance data based on the synthesized gradient data.

20. The storage device according to claim 11, wherein the step of performing the bit flipping on the at least one of the plurality of bits by the memory controller based on the third guidance data comprises:
obtaining a plurality of gradient information respectively corresponding to the plurality of bits based on the third guidance data;
comparing the plurality of gradient information to obtain a comparison result; and
flipping the at least one of the plurality of bits based on the comparison result.
